(19) United States
(12) Patent Application Publication
(10) Pub. No.: US 2011/0018006 A1
(43) Pub. Date: Jan. 27, 2011

(54) MICRO-SIZED SEMICONDUCTOR LIGHT-EMITTING DIODE HAVING EMITTING LAYER INCLUDING SILICON NANO-DOT, SEMICONDUCTOR LIGHT-EMITTING DIODE ARRAY INCLUDING THE MICRO-SIZED SEMICONDUCTOR LIGHT-EMITTING DIODE, AND METHOD OF FABRICATING THE MICRO-SIZED SEMICONDUCTOR LIGHT-EMITTING DIODE

(75) Inventors: Chul Huh, Daejeon-city (KR); Jaeheon Shin, Daejeon-city (KR); Kyung-Hyun Kim, Daejeon-city (KR); JongCheol Hong, Daejeon-city (KR); Gun-Yong Sung, Daejeon-city (KR)

Correspondence Address: AMPACC Law Group, PLLC, 6100 219th Street SW, Suite 580, Mountlake Terrace, WA, 98043, US

(73) Assignee: Electronics and Telecommunications Research Institute, Daejeon-city (KR)

(21) Appl. No.: 12/514,577

(22) PCT Filed: Oct. 31, 2007
(86) PCT No.: PCT/KR07/05469

§ 371 Date: May 12, 2009

(30) Foreign Application Priority Data
Nov. 13, 2006 (KR) 10-2006-0111874
Apr. 13, 2007 (KR) 10-2007-0036581

(51) Int. Cl. H01L 33/08; H01L 33/42; H01L 33/00

(52) U.S. Cl. 257/88; 257/98; 438/29; 257/E33.064; 257/E33.001

(57) ABSTRACT

A micro-sized semiconductor light-emitting diode includes an emission material layer formed on a silicon substrate, and including a silicon nano-dot; a hole injecting layer and an electron injecting layer that face each other, wherein the hole injecting layer and an electron injecting layer are formed between the emission material layer; a transparent conductive electrode layer formed on the electron injecting layer; and a first electrode and a second electrode that respectively inject a current in the hole injecting layer and the transparent conductive electrode layer from the outside.

### TECHNICAL FIELD

The present invention relates to a micro-sized semiconductor light-emitting diode, a semiconductor light-emitting diode array including the micro-sized semiconductor light-emitting diode, and a method of fabricating the micro-sized semiconductor light-emitting diode. This work was supported by the IT R&D program of MIC/IITA. [2006-S007-01, Ubiquitous Health Monitoring Module and System Development]

### BACKGROUND ART

A conventional semiconductor light-emitting diode has been used in a displaying device. The conventional semiconductor light-emitting diode is manufactured by using a GaAs-based and GaN-based compound semiconductor thin film.

When the semiconductor light-emitting diode is manufactured using the GaAs-based and GaN-based compound semiconductor thin film, it is difficult to grow a compound semiconductor thin film having satisfactory quality, and the cost of a substrate or the cost of a gas source for growing the compound semiconductor thin film are high. Accordingly, the manufacturing costs of the conventional semiconductor light-emitting diode are high.

In addition, since the compound semiconductor thin film used in the conventional semiconductor light-emitting diode is grown on a nonsilicon-based substrate, the conventional semiconductor light-emitting diode is integrated or connected with difficulty to a silicon electronic device that is used for driving a displaying device.

In addition, the semiconductor light-emitting diode manufactured including the GaAs-based and GaN-based compound semiconductor thin film has horizontal and vertical lengths of about 300 μm.

### DISCLOSURE OF INVENTION

### Technical Solution

The present invention provides a micro-sized semiconductor light-emitting diode that is manufactured at low manufacturing costs and is advantageous for integrating or connecting it to a silicon electronic device.

The present invention also provides a semiconductor light-emitting diode array in which a plurality of micro-sized semiconductor light-emitting diodes (unit semi-conductor light-emitting diodes) are arranged in a plurality of rows and a plurality of columns.

The present invention also provides a method of fabricating the micro-sized semi-conductor light-emitting diode.

According to an aspect of the present invention, there is provided a micro-sized semiconductor light-emitting diode including: an emission material layer formed on a silicon substrate, and including a silicon nano-dot; a hole injecting layer and an electron injecting layer that face each other, wherein the hole injecting layer and an electron injecting layer are formed between the emission material layer; a transparent conductive electrode layer formed on the electron injecting layer; and a first electrode and a second electrode that respectively inject a current in the hole injecting layer and the transparent conductive electrode layer from the outside.

The emission material layer may comprise an amorphous silicon nitride (SiN) layer. The hole injecting layer and the electron injecting layer may include a p-type silicon carbide-based material layer and a n-type silicon carbide-based material layer, respectively. The hole injecting layer may be formed on the silicon substrate, the emission material layer may be formed on the hole injecting layer, and the electron injecting layer may be formed on the emission material layer.

According to another aspect of the present invention, there is provided a semi-conductor light-emitting diode array comprising a plurality of unit semiconductor light-emitting diodes that are arranged in a plurality of row and a plurality of columns, wherein each of the unit semiconductor light-emitting diodes may include: an emission material layer formed on a silicon substrate, and including a silicon nano-dot; a hole injecting layer and an electron injecting layer that face each other, wherein the hole injecting layer and an electron injecting layer are formed between the emission material layer; a transparent conductive electrode layer formed on the electron injecting layer; and a first electrode and a second electrode that respectively inject to the hole injecting layer and the transparent conductive electrode layer from the outside, and wherein each of the unit semiconductor light-emitting diodes controls light emission by using the first electrode and the second electrode.

According to another aspect of the present invention, there is provided a method of fabricating a micro-sized semiconductor light-emitting diode, the method including: forming an emission material layer including a silicon nano-dot on a silicon substrate; forming a hole injecting layer and an electron injecting layer to face each other, wherein the hole injecting layer and the electron injecting layer are formed between the emission material layer; forming a transparent conductive electrode layer on the electron injecting layer; and forming a first electrode and a second electrode that respectively inject a current in the hole injecting layer and the transparent conductive electrode layer from the outside.

The emission material layer may include an amorphous silicon nitride (SiN) layer. The hole injecting layer may be formed by forming a p-type silicon carbide-based material layer on the silicon substrate, and the electron injecting layer is formed by forming an n-type silicon carbide-based material layer on the emission material layer. The method may further include: after forming the transparent conductive electrode layer, heat-treating the transparent conductive electrode layer at a temperature between an ambient temperature and 1000° C.

### ADVANTAGEOUS EFFECTS

The semiconductor light-emitting diode array according to the present invention can control to emit the respective micro semiconductor light-emitting diodes by using first and second electrodes that are formed between a hole injection layer and a transparent conductive electrode layer.

Since the semiconductor light-emitting diode array is formed on the silicon substrate, it is easy configure a circuit unit that can control the respective semiconductor light-emitting diodes on the silicon substrate. Accordingly, the semiconductor light-emitting diode array can be manufactured at low manufacturing costs, and the semiconductor light-emitting diode array can be used in an indoor and outdoor mini display that can be manufactured using a simple method.

### BRIEF DESCRIPTION OF THE DRAWINGS

The above and other features and advantages of the present invention will become more apparent by describing in detail exemplary embodiments thereof with reference to the attached drawings in which:

FIG. 1 is a cross-sectional view of the micro-sized semiconductor light-emitting diode according to an embodiment of the present invention;

FIG. 2 is a flow chart of a method of fabricating the micro-sized semiconductor light-emitting diode of FIG. 1, according to an embodiment of the present invention;

FIG. 3 is a plan view of a semiconductor light-emitting diode array in which a plurality of micro-sized semiconductor light-emitting diodes are arranged, according to an embodiment of the present invention;

FIG. 4 is an optical-microscopic image of the semiconductor light-emitting diode array of FIG. 3;

FIG. 5 is a graph illustrating the electrical properties of semiconductor light-emitting diode arrays according to embodiments of the present invention; and

FIG. 6 is an optical microscopic image of electrical emission of the semiconductor light-emitting diode of FIGS. 3 and 4.

### MODE FOR THE INVENTION

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art. In the drawings, the thickness of layers and region are exaggerated for clarity.

Throughout this specification, a micro-sized semiconductor light-emitting diode means a semiconductor light-emitting diode of a size of one hundred micrometers (100 μm) or less. That is, each of the horizontal and vertical lengths of a micro-sized semi-conductor light-emitting diode 200 is one hundred micrometers (100 μm) or less, preferably, 5 to 20 μm.

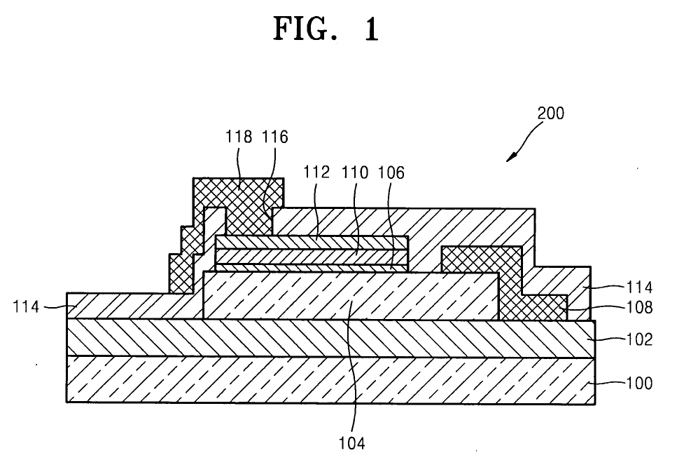

FIG. 1 is a cross-sectional view of the micro-sized semiconductor light-emitting diode according to an embodiment of the present invention.

Referring to FIG. 1, the micro-sized semiconductor light-emitting diode 200 is configured using a silicon substrate 100. When the silicon substrate 100 is used, the micro-sized semiconductor light-emitting diode 200 is advantageous for integrating or connecting it to a silicon electronic device. In addition, since the silicon substrate 100 is used in the micro-sized semiconductor light-emitting diode 200, the cost of the silicon substrate 100 is reduced, and the cost of a source gas for forming layers on the silicon substrate 100 is reduced. Accordingly, the manufacturing costs of the micro-sized semiconductor light-emitting diode 200 are reduced.

The micro-sized semiconductor light-emitting diode 200 also includes a first insulating layer 102 formed on a silicon substrate 100. The first insulating layer 102 includes a silicon oxide layer. A hole injecting layer 104 is formed on the first insulating layer 102. The hole injecting layer 104 includes a p-type silicon layer, for example, a p-type silicon carbide-based thin film. An emission material layer 106 is formed on the hole injecting layer 104. The emission material layer 106 includes a thin film having silicon nano-dots. The emission material layer 106 includes a silicon nitride (SiN) layer including the silicon nano-dots. When a thin film including the silicon nano-dots is used as the emission material layer 106, the luminous efficiency of the micro-sized semiconductor light-emitting diode 200 can be improved.

A first electrode 108 (i.e., a p-type electrode) for supplying a current to the hole injecting layer 104 is formed on one side of the hole injecting layer 104. The first electrode 108 is formed of a conductive metal material such as nickel (Ni), aluminum (Al), platinum (Pt) or gold (Au). An electron injecting layer 110 is formed on the emission material layer 106. The electron injecting layer 110 includes an n-type silicon layer, for example, an n-type silicon carbide-based thin film. An example of the silicon carbide-based thin film constituting the hole injecting layer 104 or the electron injecting layer 110 includes SiC or SiCN thin film. The hole injecting layer 104 and the electron injecting layer 110 face each other, wherein the emission material layer 106 is formed between the hole injecting layer 104 and the electron injecting layer 110.

A transparent conductive electrode layer 112 is formed on the electron injecting layer 110. The transparent conductive electrode layer 112 includes a thin film formed of any one selected from the group consisting of indium tin oxide (ITO), SnO₂, In₂O₃, Cd₂SnO₄ and ZnO. The second insulating layer 114 having a hole 116 exposing a part of a surface of the transparent conductive electrode layer 112 is formed on the transparent conductive electrode layer 112, the first electrode 108, and the hole injecting layer 104. The second insulating layer 114 includes a silicon oxide layer. The second electrode 118 (i.e., an n-type electrode) supplying a current to the transparent conductive electrode layer 112 is formed in the hole 116. The second electrode 118 is formed of a conductive metal material such as nickel (Ni), aluminum (Al), platinum (Pt) or gold (Au).

In the micro-sized semiconductor light-emitting diode 200, the hole injecting layer 104 and the electron injecting layer 110 face each other, wherein the emission material layer 106 is formed between the hole injecting layer 104 and the electron injecting layer 110. The micro-sized semiconductor light-emitting diode 200 can emit light by injecting a current through the first electrode 108 and the second electrode 118 into the hole injecting layer 104 and the transparent conductive electrode layer 112 to thereby inject holes and electrons into the emission material layer 106.

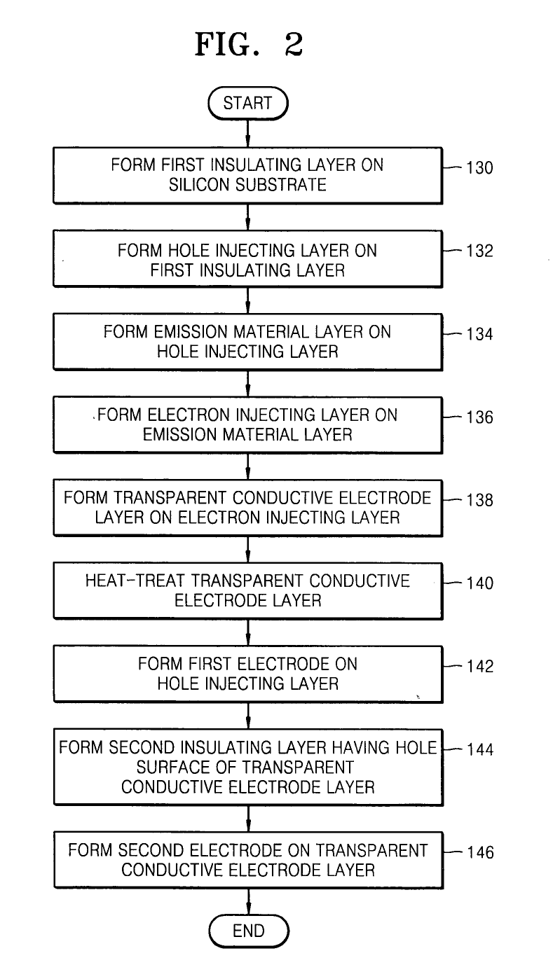

FIG. 2 is a flow chart of a method of fabricating the micro-sized semiconductor light-emitting diode of FIG. 1, according to an embodiment of the present invention.

Referring to FIG. 2, the method of fabricating the micro-sized semiconductor light-emitting diode 200 will be described with reference to FIGS. 1 and 2. The same reference numerals in FIGS. 1 and 2 denote the same elements. The first insulating layer 102 is formed on the silicon substrate 100 (step 130). The first insulating layer 102 is formed by using plasma enhanced chemical vapor deposition (PECVD), that is, by depositing a silicon oxide layer.

The hole injecting layer 104 is deposited on the first insulating layer 102 (step 132). The hole injecting layer 104 is formed using a method in which a p-type silicon layer (e.g., p-type silicon carbide-based thin film) is formed using PECVD. The hole injecting layer 104 is formed using a method in which the p-type silicon layer is formed, and then patterned. An example of the p-type silicon carbide-based thin film is SiC or SiCN thin film. The p-type silicon carbide-based thin film used as the hole injecting layer 104 is formed to a thickness of 1 Å or more.

The emission material layer 106 is formed on the hole injecting layer 104 (step 134). The emission material layer 106 includes a thin film including silicon nano-dots. The emission material layer 106 includes a silicon nitride (SiN) layer having the silicon nano-dots, and is formed to a thickness of 40 nm. An amorphous silicon nitride layer including the silicon nano-dots, which constitutes the emission material layer 106, is deposited using PECVD. The amorphous silicon nitride layer is formed using a method in which 10% argon-diluted silane and ammonia NH₃ are used as a growth gas, the temperature of the silicon substrate 100 is 250° C., the pressure of a chamber is 0.5 Torr, and RF plasma power is 5 W.

The electron injecting layer 110 is formed on the emission material layer 106 (step 136). Thus, the hole injecting layer 104 and the electron injecting layer 110 face each other, wherein the emission material layer 106 is formed between the hole injecting layer 104 and the electron injecting layer 110. The electron injecting layer 110 includes an n-type silicon layer, for example, an n-type carbide-based thin film. An example of the n-type silicon carbide-based thin film is SiC or SiCN thin film. It is sufficient that the n-type silicon carbide-based thin film used as the electron injecting layer 110 be formed to a thickness of 1 Å or more.

In the current embodiment of the present invention, the electron injecting layer 110 includes an n-type silicon carbide-based (SiC) thin film, and is formed to a thickness of 10 nm by using PECVD. The n-type silicon carbide-based thin film is formed using a method in which 10% argon-diluted silane and methane (CH₄) are used as growth gas, try-methyl-phosphite (TMP) and metalorganic source are used as doping gas, the temperature of the silicon substrate 100 is 300° C., the pressure of a chamber is 0.2 Ton, and RF plasma power is 40 W.

The transparent conductive electrode layer 112 is formed on the electron injecting layer 110 (step 138). The transparent conductive electrode layer 112 includes a thin film formed of any one selected from the group consisting of indium tin oxide (ITO), SnO₂, In₂O₃, Cd₂SnO₄ and ZnO. It is sufficient that the transparent conductive electrode layer 112 be formed to a thickness of 1 Å or more. In the current embodiment of the present invention, the transparent conductive electrode layer 112 is formed by using an ITO layer with a thickness of 100 nm by using pulsed laser deposition (PLD).

In a PLD chamber, the transparent conductive electrode layer 112 is heat-treated at a temperature between an ambient temperature and 1000° C. for 10 seconds through 1 hour to thereby form an ohmic contact between the electron injecting layer 110 (i.e., an n-type silicon carbide (SiC) layer) and the transparent conductive electrode layer 112 (i.e., an ITO layer) (step 140). In the current embodiment of the present invention, in the PLD chamber, the transparent conductive electrode layer 112 is heat-treated at a temperature of 300° C. for 30 minutes.

The emission material layer 106, the electron injecting layer 110 and the transparent conductive electrode layer 112 are formed using photolithography and a etching method after an amorphous silicon nitride layer including the silicon nano-dots, an n-type silicon carbide (SiC) layer, and an ITO layer are formed.

The first electrode 108 supplying a current to the hole injecting layer 104 is formed on one side of the hole injecting layer 104 (step 142). The first electrode 108 is formed of a conductive metal material such as nickel (Ni), aluminum (Al), platinum (Pt) or gold (Au). In the current embodiment of the present invention, the first electrode 108 is formed of nickel (Ni) and gold (Au) with respective thicknesses of 30 nm and 150 nm by using thermal evaporation.

The second insulating layer 114 having a hole 116 exposing a part of a surface of the transparent conductive electrode layer 112 is formed on the transparent conductive electrode layer 112, the first electrode 108, and the hole injecting layer 104 (step 144). The second insulating layer 114 is formed using PECVD, that is, by depositing a silicon oxide layer.

The second electrode 118 supplying a current to the transparent conductive electrode layer 112 is formed in the hole 116 (step 146). The second electrode 118 is formed of a conductive metal material such as nickel (Ni), aluminum (Al), platinum (Pt) or gold (Au). In the current embodiment of the present invention, the second electrode 118 is formed of nickel (Ni) and gold (Au) with respective thicknesses of 30 nm and 150 nm by using thermal evaporation.

The first insulating layer 102, the hole injecting layer 104, the emission material layer 106, the electron injecting layer 110 and the second insulating layer 114 are formed by using chemical vapor deposition such as PECVD in the current embodiment of the present invention; however, the present invention is not limited to the method. That is, the first insulating layer 102, the hole injecting layer 104, the emission material layer 106, the electron injecting layer 110 and the second insulating layer 114 are formed by using a known method such as physical vapor deposition.

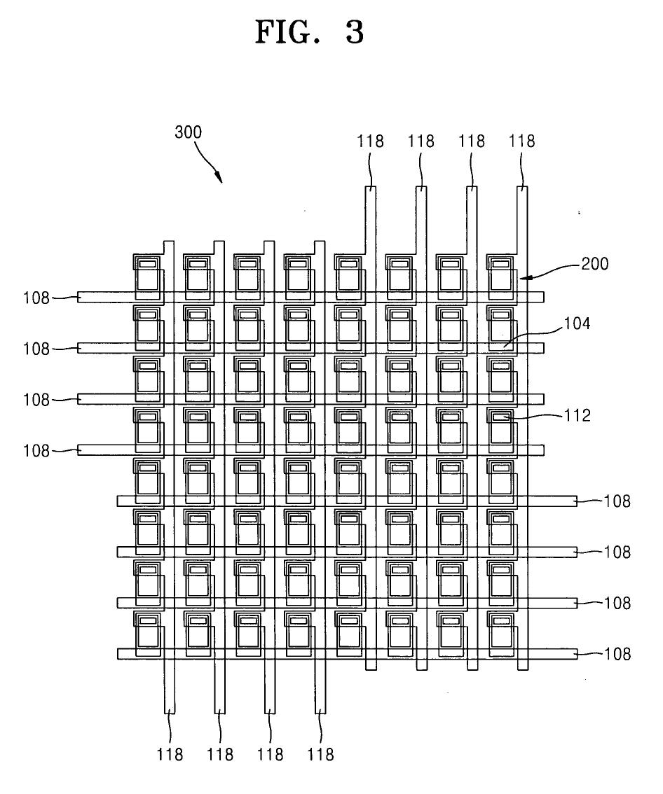

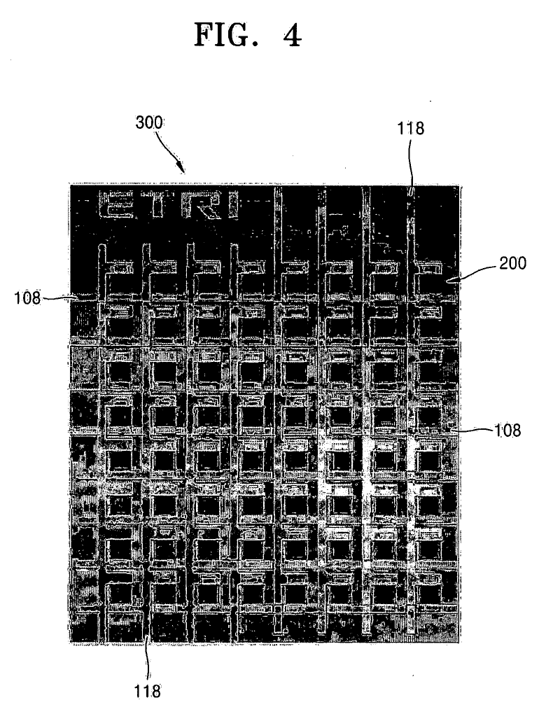

FIG. 3 is a plan view of a semiconductor light-emitting diode array in which a plurality of the micro-sized semiconductor light-emitting diodes are arranged, according to an embodiment of the present invention. FIG. 4 is an optical-microscopic image of the semiconductor light-emitting diode array of FIG. 3.

F or convenience of description, the semiconductor light-emitting diode array 300 is illustrated to have the micro-sized semiconductor light-emitting diodes 200 arranged in eight rows and eight columns. Of course, the semiconductor light-emitting diode array 300 may be formed to have the micro-sized semiconductor light-emitting diodes 200 arranged in at least two rows and at least two columns.

The semiconductor light-emitting diode array 300 is illustrated to have the micro-sized semiconductor light-emitting diodes 200 in a plurality of rows and a plurality of columns. The micro-sized semiconductor light-emitting diodes 200 are each configured to have horizontal and vertical lengths of 100 μm or less, preferably, 5 to 20 μm. Thus, the semiconductor light-emitting diode array 300 can be used in a micro-mini display.

As illustrated in FIGS. 3 and 4, the hole injecting layer 104 of each of the micro-sized semiconductor light-emitting diodes 200 is connected to a first electrode line 108 (i.e., the first electrode), and the transparent conductive electrode layer 112 of each of the micro-sized semiconductor light-emitting diodes 200 is connected to a second electrode line 118 (i.e., the second electrode). Thus, the semiconductor light-emitting diode array 300 can control light emission of the respective micro-sized semiconductor light-emitting diodes 200 by using the first electrode line 108 and the second electrode line 118.

As described above, since the semiconductor light-emitting diode array 300 is formed on the silicon substrate 100, it is easy to configure a circuit unit that can control the respective semiconductor light-emitting diodes 200 on the silicon substrate 100. Accordingly, the semiconductor light-emitting diode array 300 can be manufactured at low manufacturing costs, and can be used in an indoor and outdoor mini-display that can be manufactured using a simple method.

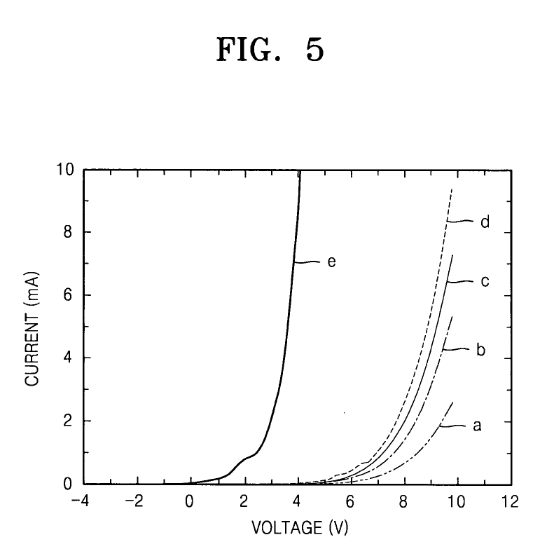

FIG. 5 is a graph illustrating the electrical properties of semiconductor light-emitting diode arrays, according to embodiments of the present invention.

Referring to FIG. 5, currents are measured with respect to voltages that are respectively applied to the semiconductor light-emitting diode arrays that respectively include 8, 16, 24, 32 and 64 micro-sized semiconductor light-emitting diodes. In FIG. 5, reference numerals a, b, c, d, and e mean curves for 8, 16, 24, 32 and 64 micro-sized semiconductor light-emitting diodes, respectively. As illustrated in FIG. 5, it can be seen that the more the micro-sized semiconductor light-emitting diodes, the greater a current with respect to the same voltage. In addition, it can be seen that when the number of the micro-sized semiconductor light-emitting diodes is 64, a current is remarkably increased at a low voltage.

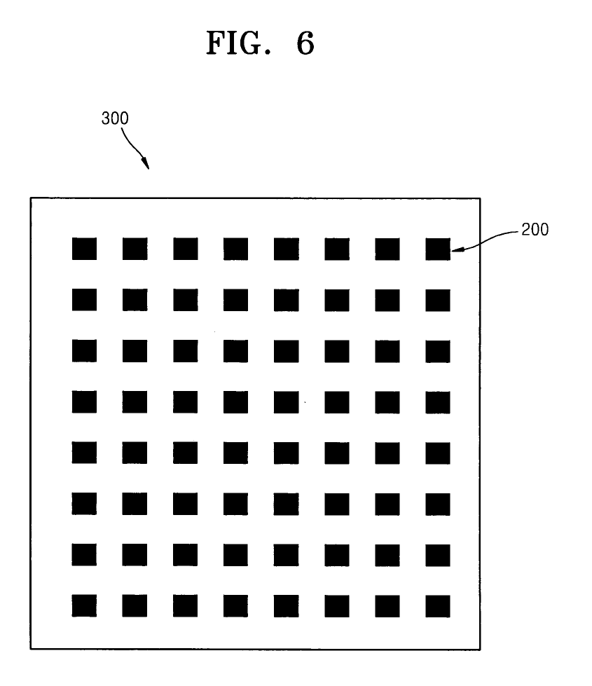

FIG. 6 is an optical microscopic image of electrical emission of the semiconductor light-emitting diode 300 of FIGS. 3 and 4.

In particular, FIG. 6 is an optical microscopic image of electrical emission measured when a voltage of 15 V is applied to the semiconductor light-emitting diode array 300. As illustrated in FIG. 6, it can be seen that the 64 micro-sized semiconductor light-emitting diodes 200 electrically-emit light regularly.

As described above, since a micro-sized semiconductor light-emitting diode according to the present invention is configured using a silicon substrate, the micro-sized semiconductor light-emitting diode is advantageous for integrating or connecting it to a silicon electronic device, and the manufacturing costs are reduced.

A n emission material layer includes a thin film including silicon nano-dots, and thus the micro-sized semiconductor light-emitting diode can improve luminous efficiency.

Since the micro-sized semiconductor light-emitting diode has a size of several through several tens of micrometers, the micro-sized semiconductor light-emitting diode can be used in a micro-mini display.

The semiconductor light-emitting diode array according to the present invention can control to emit the respective micro semiconductor light-emitting diodes by using first and second electrodes that are formed between a hole injection layer and a transparent conductive electrode layer.

Since the semiconductor light-emitting diode array is formed on the silicon substrate, it is easy configure a circuit unit that can control the respective semiconductor light-emitting diodes on the silicon substrate. Accordingly, the semiconductor light-emitting diode array can be manufactured at low manufacturing costs, and the semiconductor light-emitting diode array can be used in an indoor and outdoor mini display that can be manufactured using a simple method.

While the present invention has been particularly shown and described with reference to exemplary embodiments thereof, it will be understood by one of ordinary skill in the art that various changes in form and details may be made therein without departing from the spirit and scope of the present invention as defined by the following claims.

### INDUSTRIAL APPLICABILITY

The present invention provides a micro-sized semiconductor light-emitting diode, a semiconductor light-emitting diode array including the micro-sized semiconductor light-emitting diode, and a method of fabricating the micro-sized semiconductor light-emitting diode.

1. A micro-sized semiconductor light-emitting diode comprising:
an emission material layer formed on a silicon substrate, and including a silicon nano-dot;
a hole injecting layer and an electron injecting layer that face each other, wherein the hole injecting layer and an electron injecting layer are formed between the emission material layer;
a transparent conductive electrode layer formed on the electron injecting layer; and
a first electrode and a second electrode that respectively inject a current in the hole injecting layer and the transparent conductive electrode layer from the outside.

2. The micro-sized semiconductor light-emitting diode of claim 1, wherein the emission material layer comprises an amorphous silicon nitride (SiN) layer.

3. The micro-sized semiconductor light-emitting diode of claim 1, wherein the hole injecting layer and the electron injecting layer comprise a p-type silicon carbide-based material layer and a n-type silicon carbide-based material layer, respectively.

4. The micro-sized semiconductor light-emitting diode of claim 1, wherein the transparent conductive electrode layer is formed of any one selected from the group consisting of indium tin oxide (ITO), SnO₂, In₂O₃, Cd₂SnO₄ and ZnO.

5. The micro-sized semiconductor light-emitting diode of claim 1, wherein the hole injecting layer is formed on the silicon substrate, the emission material layer is formed on the hole injecting layer, and the electron injecting layer is formed on the emission material layer.

6. A semiconductor light-emitting diode array comprising a plurality of unit semi-conductor light-emitting diodes that are arranged in a plurality of row and a plurality of columns,
wherein each of the unit semiconductor light-emitting diodes comprises: an emission material layer formed on a silicon substrate, and including a silicon nano-dot; a hole injecting layer and an electron injecting layer that face each other, wherein the hole injecting layer and an electron injecting layer are formed between the emission material layer; a transparent conductive electrode layer formed on the electron injecting layer; and a first electrode and a second electrode that respectively inject to the hole injecting layer and the transparent conductive electrode layer from the outside, and
wherein each of the unit semiconductor light-emitting diodes controls light emission by using the first electrode and the second electrode.

7. The semiconductor light-emitting diode array of claim 6, wherein the emission material layer comprises an amorphous silicon nitride (SiN) layer.

8. The semiconductor light-emitting diode array of claim 6, wherein each of the horizontal and vertical lengths of the unit semiconductor light-emitting diodes is 100 μm or less.

9. A method of fabricating a micro-sized semiconductor light-emitting diode, the method comprising:
forming an emission material layer including a silicon nano-dot on a silicon substrate;
forming a hole injecting layer and an electron injecting layer to face each other, wherein the hole injecting layer and the electron injecting layer are formed between the emission material layer;
forming a transparent conductive electrode layer on the electron injecting layer; and
forming a first electrode and a second electrode that respectively inject a current in the hole injecting layer and the transparent conductive electrode layer from the outside.

10. The method of claim 9, wherein the emission material layer comprises an amorphous silicon nitride (SiN) layer.

11. The method of claim 9, wherein the hole injecting layer is formed by forming a p-type silicon carbide-based material layer on the silicon substrate, and the electron injecting layer is formed by forming an n-type silicon carbide-based material layer on the emission material layer.

12. The method of claim 9, further comprising:
after forming the transparent conductive electrode layer,
heat-treating the transparent conductive electrode layer at a temperature between an ambient temperature and 1000° C.
